(19) United States
(12) Patent Application Publication
(10) Pub. No.: US 2008/0094928 A1
(43) Pub. Date: Apr. 24, 2008

(54) Semiconductor memory having data line separation switch

(75) Inventor: Yoshisato Yokoyama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/976,266

(22) Filed: Oct. 23, 2007

(30) Foreign Application Priority Data
Oct. 24, 2006 (JP) 288693/2006

(51) Int. Cl. G11C 7/00

(52) U.S. Cl. 365/205

(57) ABSTRACT

A semiconductor memory comprises a data line separation switch circuit, which controls connection and separation of digit lines DT/DB connected to a memory cell and sense amplifier, and a control circuit, which performs a control of switching the data line separation switch circuit from turning-on to turning-off according to the level of the amplification output of the sense amplifier at the sense operation time. Detecting the output level of the sense amplifier so as to separate the sense amplifier from the digit lines makes it difficult for an error read to occur, and at the same time, adjusting a timing of the data line separation switch is made unnecessary.

### BACKGROUND OF THE INVENTION

1. Field of the Invention

The present invention relates to a semiconductor memory, and in particular, to a semiconductor memory having a switch circuit which controls the connection of a pair of digit lines and a sense amplifier.

2. Description of Related Art

In general, a semiconductor memory includes, for example, as shown in FIG. 5, those provided with a data line separation switch circuit 103 between a pair of digit lines and a sense amplifier in order to suppress a power loss caused by charge and discharge of a digit line (bit line) in the data read operation. In the sense operation, the data line separation switch circuit 103 separates a pair of data lines DLDT/DLDB connected to the sense amplifier from a pair of digit lines DT/DB connected to a memory cell array, and the sense amplifier amplifies a read signal based on the difference between electrical charges of the pair of data lines DLDT/DLDB.

The semiconductor memory comprising the data line separation switch circuit will be described with reference to FIGS. 5 and 6. As shown in FIG. 5, a memory cell 101 is provided at a crossing portion of the pair of digit lines DT/DB and word lines (WORD0, WORD1, . . . ) respectively. The pair of digit lines DT/DB connected to a Y selector 102 is connected to a sense amplifier 104 through data line separation switch circuit 103 when the Y selector 102 is turned on by a column selection signal. In the data read operation, the data signals (read data) of the pair of data lines DLDT/DLDB amplified by the sense amplifier 104 are outputted to a data output terminal DO from an output circuit 105.

The memory cell 101 shown in FIG. 5 is a memory cell of a static random access memory (SRAM) as schematically shown in FIG. 6 and comprises a flip-flop mutually connecting the inputs and outputs of two inverters INV1 and INV2. Between the connection nodes of the inverters INV1 and INV2 and the pair of data lines DT/DB, access transistors MN1 and MN2 are connected respectively, and the gates of the access transistors MN1 and MN2 are commonly connected to the word line WORD. In the data read operation, the access transistors connected to the activated word line are turned on, and the potentials of two nodes of the flip-flop are transmitted to the pair of data lines DT/DB.

In FIG. 5, the sense amplifier 104 is a latch type sense amplifier. The sense amplifier 104 comprises a PMOS transistor PM1 whose source is connected to a high potential power supply, an NMOS transistor NM1 whose drain and gate are connected to the drain and the gate of the PMOS transistor PM1 respectively, a PMOS transistor PM2 whose source is connected to a high potential power supply, an NMOS transistor NM2 whose drain and gate are connected to the drain and the gate of the PMOS transistor NM2 respectively, and an NMOS transistor NM3 whose drain is connected to the commonly connected source of the NMOS transistors NM1 and NM2 and whose source is connected to a low potential power supply and whose gate is inputted with a sense amplifier control signal SES.

The common drain of the PMOS transistor PM1 and the NMOS transistor NM1 is connected to a data line DLDT, and is also connected to the common gate of the PMOS transistor PM2 and the NMOS transistor NM2. The common drain of the PMOS transistor PM2 and the NMOS transistor NM2 is connected to a data line DLDB, and is also connected to the common gate of the PMOS transistor PM1 and the NMOS transistor NM1.

When the sense amplifier control signal SES assumes a high level as an active level, the NMOS transistor NM3 is turned on, and supplies a current to the sense amplifier 104. The sense amplifier 104 amplifies difference in potential between the pair of data lines DLDT/DLDB so that one data line has a low potential power supply voltage when the other data line has a high potential power supply voltage, and outputs a binary complementary signal.

The data line separation switch circuit 103 comprises transfer gates (for example, PMOS transistor) connected between the pair of data lines DLDT/DLDB and a pair of outputs YDT/YDB of the Y selector 102. The data line separation switch circuit 103 is turned off when the sense amplifier control signal SES is at a high level (when the sense amplifier 104 is activated), and is turned on when the sense amplifier control signal SES is at a low level as an inactive level.

In FIG. 5, for ease of explanation, one pair of digit lines DT/DB only are shown from among a plurality of pairs of digit lines of the memory cell array. However, the semiconductor memory includes a plurality of Y selectors corresponding to the plurality of pairs of digit lines and the Y selectors are connected to a pair of common data lines YDT/YDB. One of the Y selectors 102 is turned on by a column selection signal from an unillustrated column decoder. While the Y selector 102 is turned on, the word line is activated. Further, in FIG. 5, the pre-charge circuit for the digit line is not shown. Further, in FIG. 5, a latch circuit which latches write data from a data input terminal, a write buffer which receives the output of the latch circuit and drive-outputs a complementary write data signal to a pair of outputs, and a write data bus which connects the pair of outputs of the write buffer with the pair of common data lines or the like are omitted.

The sense amplifier 104 is activated at a timing of turning-off the data line separation switch circuit 103. At this time, an error read by the sense amplifier 104 is liable to occur. This is because a parasite capacity of the pair of data lines DLDT/DLDB is smaller than the parasite capacity of the pair of digit lines DT/DB of the memory cell array side, and this reverses the potentials of the pair of data lines DLDT/DLDB when the sense amplifier is activated, thereby causing the error read liable to occur. For example, prior to the amplification of the difference in potential between the pair of data lines DLDT/DLDB by the sense amplifier 104, when the data line separation switch circuit 103 is switched from turning-on to turning-off, a common drain node n1 of the PMOS transistor PM1 and the NMOS transistor NM1 and a common drain node n2 of the PMOS transistor PM2 and the NMOS transistor NM2 of the sense amplifier 104 are put into a floating state. After that, when an NMOS transistor NM3 is turned on and the sense amplifier 104 is activated, one of the nodes n1 and n2 has its electric charge discharged, and is pulled down to a GND potential side. However, since the parasite capacity of the pair of data lines DLDT/DLDB is small and its stored charge is also small, there are often the cases where, due to the variability of the capacity component, the threshold voltage, and the like of the transistor comprising the sense amplifier 104, the potentials of the pair of data lines DLDT/DLDB are reversed. For example, while the node n1 should be primarily taken as the GND potential, the NMOS transistor NM1 is not turned on. On the contrary, the NMOS transistor NM2 of the node n2 ends up turning-on, and thus, the node n2 becomes the GND potential, and the node n1 becomes the power supply potential, thereby often causing the error read.

Hence, Japanese Patent Laid-Open No. 2004-62940 discloses, as shown in FIG. 7, the data line separation switch circuit 103 is turned off by a timing of delaying the sense amplifier activation control signal SES by a delay element 107. That is, the sense amplifier activation control signal SES is raised to a high level, and the sense operation is performed by the sense amplifier 104. When a potential difference becomes large between the common drain node n1 of the PMOS transistor PM1 and the NMOS transistor NM1 and the common drain node n2 of the PMOS transistor PM2 and the NMOS transistor NM2, the data line separation switch circuit 103 is turned off and the pair of data lines DLDT/DLDB is separated from the pair of digit lines DT/DB.

The semiconductor memory shown in FIG. 7 adjusts the delay from the activation of the sense amplifier 104 to the turning-off of the data line separation switch circuit 103 by providing the delay circuit 107. Consequently, the configuration shown in FIG. 7 causes an area-wise disadvantage of the circuit. For example, when the delay needs to be great, the area-wise disadvantage is great. Further, a circuit designer needs a labor hour to adjust the timing of turning-on to turning-off the data line separation switch circuit 103, that is, a labor hour to adjust the delay of the delay circuit 107.

The present inventor has recognized that the semiconductor memory shown in FIG. 5 is liable to cause an error read of the sense amplifier because the input voltage of the sense amplifier is liable to become small as the voltage is reduced.

Further, the present inventor has recognized that the semiconductor memory shown in FIG. 7 causes the area-wise disadvantage due to the provision of the delay element. Further, the circuit designer needs a labor hour to adjust a timing of separating the data lines.

### SUMMARY

The semiconductor memory according to the present invention comprises a data line separation switch which controls connection and separation of a pair of digit lines connected to a memory cell and a sense amplifier; and a control circuit which performs switching a data line separation switch from turning-on to turning-off according to an output level of the sense amplifier at the sense operation time, and controlling the separation of the sense amplifier from the pair of digit lines.

According to the present invention, the invention is configured to detect the output level of the sense amplifier at the sense operation time so as to be separated from the sense amplifier and the digit line, so that a high sensitivity sense amplifier circuit is realized, which avoids the generation of an error read and suppresses and decreases the error read.

Further, according to the present invention, the invention is configured to perform a control of timing to separate the sense amplifier from the digit lines based on the output level of the sense amplifier, so that the area-wise disadvantage in performing the timing control by the delay element is removed, and moreover, at the circuit design time or the like, the designer has no need for a labor hour to adjust a timing of separating the digit lines.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram of a semiconductor memory showing the configuration of one embodiment of the present invention;

FIG. 2 is a level detection circuit diagram of one embodiment of the present invention;

FIG. 3 is a view showing a configuration of a data line separation switch of one embodiment of the present invention;

FIG. 4 is a view showing an operation waveform of the semiconductor memory in FIG. 1;

FIG. 5 is a circuit diagram of the conventional semiconductor memory;

FIG. 6 is a view schematically showing a memory cell of the semiconductor memory; and

FIG. 7 is a view showing another configuration of the conventional semiconductor memory.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The present invention does not use a delay circuit for controlling a timing of separating a sense amplifier from digit lines, but by detecting the output potential of the sense amplifier, generates a timing of turning-off a data line separation switch circuit.

In detail, the semiconductor memory according to the present invention comprises: a data line separation switch circuit (103) which controls connection and separation between a pair of digit lines (DT/DB) connected to a memory cell (101) and a pair of data lines (DLDT/DLDB) connected to a sense amplifier; and a control circuit (106) which controls the data line separation switch circuit (103) according to the output level of the sense amplifier (104) at the sense operation time, so that the control circuit (106) separates the sense amplifier (104) from the pair of digit lines (DT/DB). The control circuit (106) is preferably a level detection circuit, which inputs the pair of data lines (DLDT/DLDB), and upon detecting that either one of the pair of data lines changes from a pre-charge potential to a predetermined level set in advance, activates a feedback signal (FB) and supplies this signal to the data line separation switch circuit (103). The sense amplifier (104), at the sense operation starting time, amplifies a difference in potential between the pair of data lines (DLDT/DLDB) connected to the pair of digit lines (DT/DB) through the data line separation switch circuit (103). The sense amplifier (104), after either one of the signals of the pair of data lines changes to a predetermined level set in advance from the pre-charge potential, amplifies the difference in potential between the pair of data lines (DLDT/DLDB) separated from the selected pair of digit lines.

Similarly to the conventional circuit, in the configuration adjusting the timing by the delay circuit, when the delay from a timing of activating the sense amplifier to turning-off the data line separation switch becomes large, the circuit area of the delay circuit becomes large. However, according to the present invention, even in such a case, without causing any area-wise disadvantage, a timing of separating the sense amplifier from the digit lines can be generated, and this will be described in detail in the following embodiment.

### Embodiment

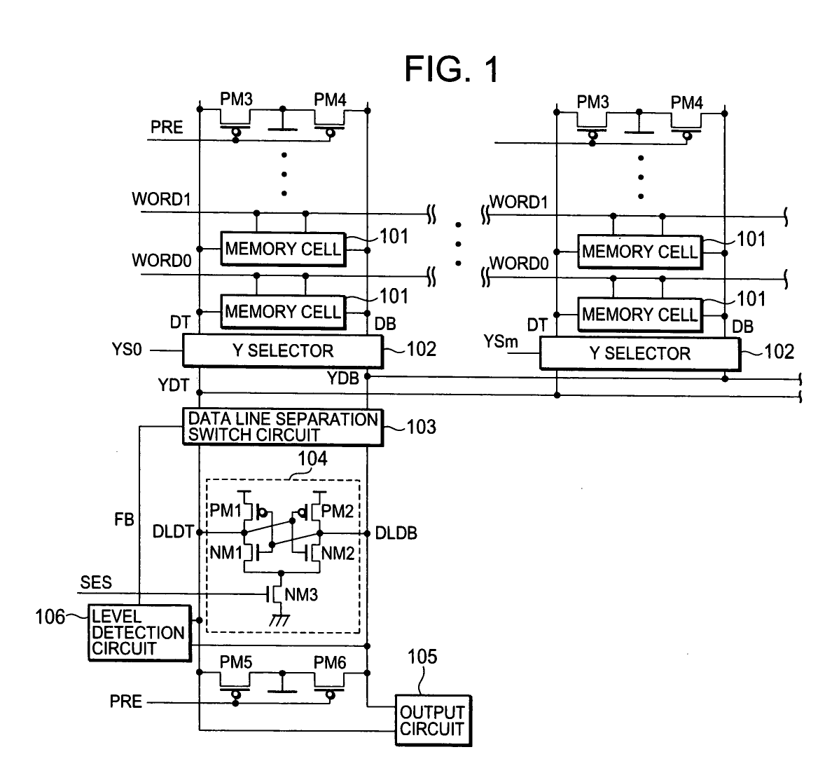

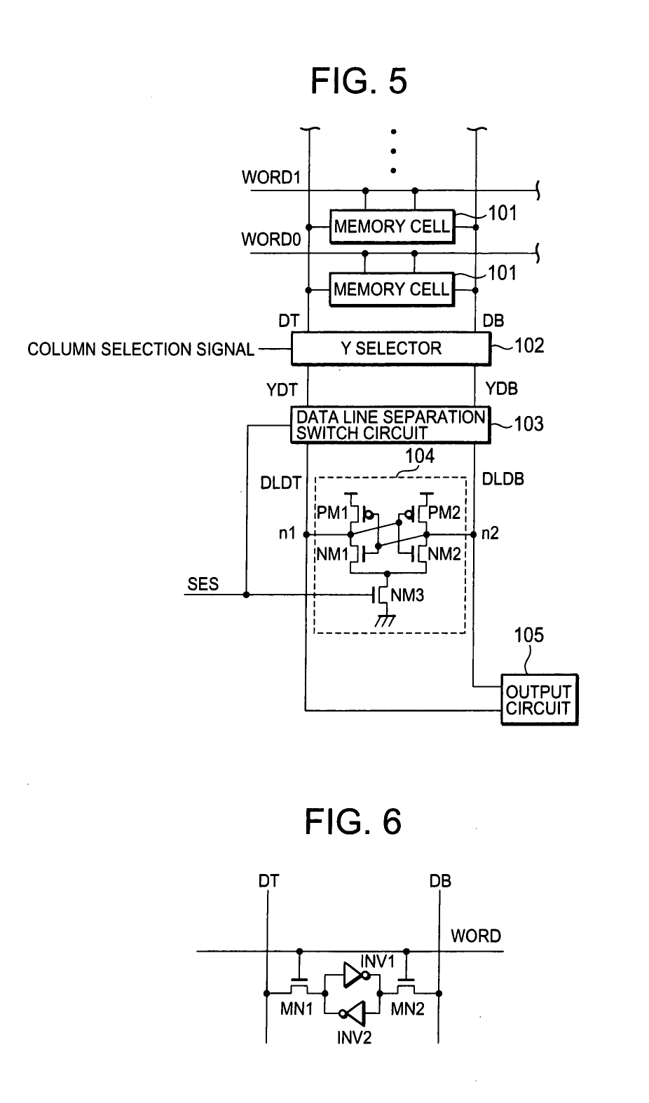

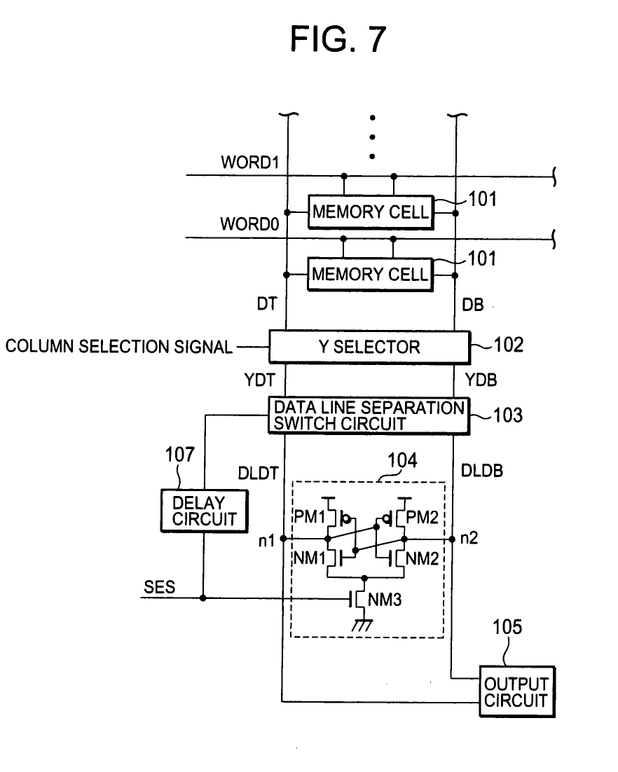

In FIG. 1, the components having identical or equivalent functions as FIGS. 5 and 7 are attached with identical reference numerals. A memory cell 101 is configured as shown in FIG. 6. Here, a plurality of columns (pair of digit lines) inside a memory cell array are written in FIG. 1, and one of a plurality of Y selectors 102 connected to an associated one of plurality of pair of digit lines is selected by a column selection signal (YS0, . . . , YSm) supplied from an unillustrated column decoder. Further, in FIG. 1, similarly to FIG. 5, a latch circuit which latches a write data from the input terminal, a write buffer, and a write data bus or the like are omitted.

Referring to FIG. 1, a semiconductor memory according to the present embodiment comprises a level detection circuit 106 to detect a signal voltage level of a pair of data lines DLDT/DLDB as a circuit which control a timing of turning-off the data line separation switch circuit 103 during the sense operation time. Upon, detecting that a sense amplifier 104 amplifies a difference in potential between the pair of data lines DLDT/DLDB to a predetermined level, the level detection circuit 106 outputs a feedback signal FB to turn-off the data line separation switch circuit 103.

PMOS transistors PM3 and PM4, which are connected between a digit line DT and a power supply and between a digit line DB and a power supply, respectively, and controlled by a pre-charge control signal PRE, are pre-charge transistors of the pair of digit lines DT/DB. PMOS transistors PM5 and PM6, which are connected between a data line DLDT and a power supply, and between a data line DLDB and a power supply, respectively, and controlled a pre-charge control signal PRE, are pre-charge transistors of the pair of data lines DLDT/DLDB. The pair of digit lines DT/DB and the pair of data lines DLDT/DLDB are pre-charged to the power supply potential when the pre-charge control signal PRE is set to a low level as an active level prior to a read access.

When a sense amplifier activation control signal SES is raised to a high level as an active level, an NMOS transistor NM3 is turned on, and the sense amplifier 104 is activated. At this time, the data line separation switch circuit 103 is put into an on-state (a feedback signal FB is set to a low level as a non-active level), and the pair of digit lines DT/DB (that is, the pair of digit lines DT/DB selected by a column address) connected to the Y selector 102 which is turned-on by a column selection signal (YS0, . . . , YSm) and the pair of data lines DLDT/DLDB connected to the sense amplifier are electrically conducted respectively. Between data lines DT and DB which are the selected pair of digit lines, a difference in potential is generated according to the data of the memory cell connected to a selection word line. This difference in potential is amplified by the sense amplifier 104, and one of the pair of digit lines DT/DB is raised to a high level, and the other is set to a low level.

The level detection circuit 106, upon receipt of the signals of the pair of data lines DLDT/DLDB and detecting that one of the pair of data lines DLDT/DLDB drops to a predetermined level from the pre-charge potential by the amplification operation of the sense amplifier 104, sets a feed back signal FB which was at a low level so far to a high level as an active level. Upon receipt of the feed back signal FB of a high level, the data line separation switch circuit 103 turns-off.

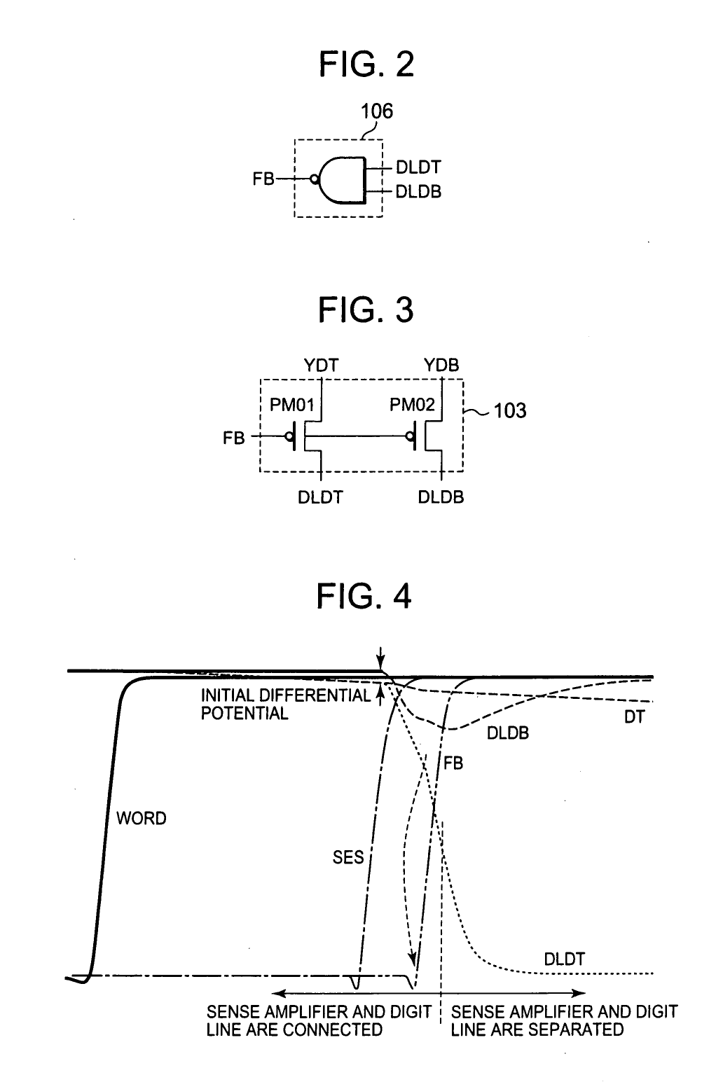

FIG. 2 is a view showing one example of the configuration of the level detection circuit 106. As shown in FIG. 2, the level detection circuit 106 comprises a two-input NAND circuit with the pair of data lines DLDT/DLDB taken as an input. When the pair of data lines DLDT/DLDB are both at the pre-charge potential (power supply potential), the NAND circuit outputs a low level as a non-active level. When one of the pair of data lines DLDT/DLDB transits to a low level, the NAND circuit outputs a high level as an active level. That is, when the potential of one of the pair of data lines DLDT/DLDB is reduced lower than a threshold value Vthp of the PMOS transistor which forms the two-input NAND circuit for the power supply potential, the two-input NAND circuit outputs a high level.

The data line separation switch circuit 103, which receives the feedback signal FB serving as an output of the level detection circuit 106 including the two-input NAND circuit, comprises, for example, as shown in FIG. 3, PMOS transistor PM01 and PM02, which input the feedback signal FB to the gate. When the feedback signal FB is at a low level, the PMOS transistors PM01 and PM02 of the data line separation switch circuit 103 are turned on, and YDT and DLDT are connected, and YDB and DLDB are connected. When the feedback signal FB is at a high level, the PMOS transistors PM01 and PM02 of the data line separation switch circuit 103 are turned off. Alternatively, in place of the PMOS transistor, the data line separation switch circuit 103 may comprise a CMOS transfer gate comprised of the PMOS transistor which inputs the feedback signal FB to the gate and the NMOS transistor which inputs an inversion signal of FB to the gate.

One example of the operation of the present embodiment will be described as follows. The feedback signal FB from the level detection circuit 106, which receives the pre-charged pair of data lines DLDT/DLDB (both of them at a high level) at the read access time, drops to a low level, and the data line separation switch circuit 103 is turned on. Further, the Y selector 102 selected by the column selection signal YS0 is turned on, the data signal of the memory cell 101 connected to a selection word line (for example, WORD 1) is outputted to a complementary pair of digit lines DT/DB, and is outputted to the common pair of data lines YDT and YDB through the Y selector 102 which is in a on-state. Further, the data signal is transmitted to the pair of data lines DLDT/DLDB through the data line separation switch circuit 103 which is in an on-state. The sense amplifier 104, upon receipt of the sense amplifier control signal SES of a high level at the sense operation time, is activated, and latch-amplifies the signals of the pair of data lines DLDT/DLDB.

Upon receipt of the signals of the pair of data lines DLDT/DLDB, the feedback signal FB serving as an output of the level detection circuit 106 changes from a low level to a high level. Responding to the change of the feedback signal FB, the data line separation switch circuit 103 changes from turning-on to turning-off, and after that, the sense amplifier 104 is put into a state cut off from the pair of digit lines, and amplifies the read data.

FIG. 4 is a view showing a waveform (SPICE simulation result) of the operation of the embodiment of FIG. 1. In a state in which the pair of digit lines DT/DB and the pair of data lines DLDT/DLDB are connected, by the amplification of the sense amplifier 104, a potential of one of the pair of data lines (in this case, it is DLDT) falls down. Corresponding to potential change of one of the pair of data lines, the feedback signal FB rises to a high level, and the data line separation switch circuit 103 turns off. Thus, the sense amplifier 104, in a state of being cut off from the digit lines DT/DB, amplifies the difference in potential between the pair of data lines DLDT/DLDB, and as a result, the data line DLDT is set to a low level, and the data line DLDB is raised to a high level.

In the present embodiment, even when the sense amplifier 104 is activated in a state in which the data line separation switch circuit 103 is turned on, that is, in a state in which the selected pair of digit lines DT/DB and pair of data lines DLDT/DLDB are connected, the pair of digit lines DT/DB are large in parasite capacity (large comparing with the parasite capacity of the pair of data lines DLDT/DLDB), and therefore, keep the initial differential potential (see FIG. 4: the read potential of the selected memory cell) to some extent. The sense amplifier 104 given the initial differential potential starts amplifying the difference in potential between the pair of data lines DLDT/DLDB, and when the difference in potential between the pair of data lines DLDT/DLDB reach a predetermined level or more, the pair of data lines DLDT/DLDB are cut off from the pair of digit lines DT/DB. Hence, a possibility of generating an error read reversing the potentials of the pair of data lines DLDT/DLDB is particularly reduced, thereby realizing a high sensitivity sense amplifier having few read error. Further, the pair of digit lines and the pair of data lines are separated with a timing of sufficiently amplifying the difference in potential between of the pair of data lines DLDT/DLDB, and therefore, the power consumption is also suppressed.

Further, in the present embodiment, since an appropriate timing of separating the data lines are automatically generated from the circuit 106 which detects a level of the data lines, the designer does not need to adjust a timing of separating the data lines by using a delay circuit similarly to the conventional circuit. That is, the designer has no need for labor hour to adjust a timing of separating the data lines.

Further, according to the present invention, the level detection circuit 106 which generate a timing of separating the data lines is, for example, configured as the two-input NAND circuit, and its occupying area is assumed to be small. Incidentally, the level detection circuit 106 may receive DLDT/DLDB at an inverter stage (may become an OR circuit), and can be configured with a small area as comparing with the case where a timing is generated by the delay element (see FIG. 7).

It is apparent that the present invention is not limited to the above embodiments, but may be modified and changed without departing from the scope and spirit of the invention.

What is claimed is:

1. A semiconductor memory circuit, comprising:
a pair of digit lines connected to a plurality of memory cells;
a pair of data lines;
a sense amplifier connected between said pair of data lines and amplifying a difference in potential between said data lines;
a switch circuit connected between said pair of data lines and said pair of digit lines; and
a control circuit controlling said switch circuit to separate said pair of digit lines from said pair of data lines in response to output of said sense amplifier.

2. The semiconductor memory circuit according to claim 1, wherein said switch circuit separates said pair of digit lines from said pair of data lines when the difference in potential reached a predetermined level.

3. The semiconductor memory circuit according to claim 1, wherein said switch circuit separates said pair of digit lines from said pair of data lines when a voltage of at least one of said pair of data lines changes from a pre-charge voltage to a predetermined voltage.

4. The semiconductor memory circuit according to claim 1, further comprising a plurality of additional pairs of digit lines, one of the pair of said digit lines and the additional pairs of digit lines is electrically connected to the switch circuit.

5. The semiconductor memory circuit according to claim 1, wherein said sense amplifier is kept activated after said switch circuit separates said pair of data lines from said pair of digit lines.

6. The semiconductor memory circuit according to claim 2, wherein said control circuit includes a NAND circuit supplied with signals of said pair of data lines.

7. The semiconductor memory circuit according to claim 1, wherein said memory cells are static random access memory.
